(19) United States
(12) Patent Application Publication
(10) Pub. No.: US 2014/0007933 A1
(43) Pub. Date: Jan. 9, 2014

(54) THIN FILM SOLAR CELL AND METHOD OF MANUFACTURING THE SAME

(71) Applicants: Seoung Yoon RYU, Gyeonggi-do (KR); Dong Ho KIM, Gyeongsangnam-do (KR); Kee Seok NAM, Gyeongsangnam-do (KR); Yong Soo JEONG, Gyeongsangnam-do (KR); Jung Dae KWON, Gyeongsangnam-do (KR); Sung Hun LEE, Gyeongsangnam-do (KR); Jung Heum YUN, Gyeongsangnam-do (KR); Gun Hwan LEE, Gyeonggi-do (KR); Hyung Hwan JUNG, Gyeonggi-do (KR); Sung Gyu PARK, Gyeongsangnam-do (KR); Chang Su KIM, Gyeongsangnam-do (KR); Jae Wook KANG, Gyeongsangnam-do (KR); Keong Su LIM, Daejeon (KR); Sang II PARK, Chungcheongbuk-do (KR)

(72) Inventors: Seoung Yoon RYU, Gyeonggi-do (KR); Dong Ho KIM, Gyeongsangnam-do (KR); Kee Seok NAM, Gyeongsangnam-do (KR); Yong Soo JEONG, Gyeongsangnam-do (KR); Jung Dae KWON, Gyeongsangnam-do (KR); Sung Hun LEE, Gyeongsangnam-do (KR); Jung Heum YUN, Gyeongsangnam-do (KR); Gun Hwan LEE, Gyeonggi-do (KR); Hyung Hwan JUNG, Gyeonggi-do (KR); Sung Gyu PARK, Gyeongsangnam-do (KR); Chang Su KIM, Gyeongsangnam-do (KR); Jae Wook KANG, Gyeongsangnam-do (KR); Keong Su LIM, Daejeon (KR); Sang II PARK, Chungcheongbuk-do (KR)

(73) Assignee: KOREA INSTITUTE OF MACHINERY & MATERIALS, Daejeon (KR)

(21) Appl. No.: 13/571,807

(22) Filed: Aug. 10, 2012

(30) Foreign Application Priority Data
Jul. 6, 2012 (KR) 10-2012-0073834

(51) Int. Cl. H01L 31/0224; H01L 31/18; H01L 31/0216; H01L 31/20

(52) U.S. Cl. 136/256; 438/96; 438/97; 438/98; 257/E31.045; 257/E31.048; 257/E31.051

(57) ABSTRACT

Disclosed are a thin film solar cell and a method of manufacturing the thin film solar cell. The thin film solar cell according to an exemplary embodiment of the present invention thin film solar cell includes a substrate: a front electrode layer formed on the substrate; an oxide layer formed on the front electrode layer: a light absorbing layer (intrinsic layer) formed on the oxide layer; and a back electrode layer formed on the light absorbing layer, wherein the oxide layer is formed of a material selected from MoO₂, WO₂, V₂O₅, NiO and CrO₃.

### CROSS-REFERENCE TO RELATED APPLICATION

This application claims priority to and the benefit of Korean Patent Application No. 10-2012-0073843 filed in the Korean Intellectual Property Office on Jul. 6, 2012, the entire contents of which are incorporated herein by reference.

### TECHNICAL FIELD

The present invention relates to a solar cell, and more particularly, to a thin film solar cell.

### BACKGROUND OF THE INVENTION

A thin film solar cell may be variously classified according to a thin film deposition temperature, a type of substrates used, and a deposition method, and may be generally classified into an amorphous silicon thin film solar cell and a crystalline silicon thin film solar cell according to a crystalline property of a light absorbing layer (intrinsic layer).

The thin film solar cell, which uses a thin film as a light absorbing layer, has a light absorption coefficient much higher than that of a crystalline silicon solar cell and may use a low-price substrate, such as glass or a metal plate, instead of a high-price silicon substrate, so that it has an advantage in that a cost of a substrate material is very low compared to the crystalline solar cell. Further, the thin film solar cell has an advantage in that it may be fabricated based on LCD producing technology, thereby greatly reducing initial investment costs of the facilities, and a low-temperature process may be employed, thereby implementing a device using a flexible substrate, such that many researches on the thin film solar cell have been recently conducted.

The thin film solar cell having the aforementioned structure in the related art includes a substrate on which light is incident, and a TCO layer, a p-type semiconductor layer(a-Si:H), an i-type semiconductor layer(a-Si:H), an n-type semiconductor layer(a-Si:H), and a back electrode which are sequentially deposited on the substrate.

More particularly, the thin film solar cell in the related art has a form in which the i-type semiconductor layer that is an intrinsic semiconductor having no impurities is interposed between the p-type semiconductor layer and the n-type semiconductor layer having a high doping concentration, and such a structure is generally referred to as a p-i-n structure. In such a structure, the i-type semiconductor is depleted by the p-type semiconductor layer and the n-type semiconductor layer having a high doping concentration, and thus electron-hole pairs generated by the incident light in the i-type semiconductor layer are collected in each interface due to drift by an internal electric field, to generate a current.

However, the aforementioned thin film solar cell having the p-i-n structure has the following problems. First, light stability is relatively low due to an increase of defects by doping layers, such as the p-type semiconductor layer and the n-type semiconductor layer, so that degradation is generated in a case where the solar cell is exposed to light.

Second, since the p-type semiconductor layer and the n-type semiconductor layer are formed so as to have a high doping concentration, there are concerns about a worker being exposed to toxic gas because the toxic gas is generated during the process, and thus this negatively affects a working environment.

Third, the p-i-n layers are all deposited using a plasma enhanced chemical vapor deposition (PECVD) process using SiH₄ and H₂ gas. The PECVD has a problem in that costs for a process and initial investment costs for facilities are increased, compared to a thermal evaporation process or a sputtering process.

All of the aforementioned problems are caused because the thin film solar cell of the p-i-n structure uses the doping layers, such as the p-type semiconductor layer and the n-type semiconductor layer, so that attempts to remove the p-type semiconductor layer and/or the n-type semiconductor layer that is the doping layer or replace the p-type semiconductor layer and/or the n-type semiconductor layer with another material have been conducted.

In regards to this, research on the replacement of the n-type semiconductor layer with an LiF/Al Schottky junction in the p-i-n structure has been recently disclosed (Liang Fang et. al., IEEE TRANSACTIONS ON ELECTRON DEVICES, VOL. 58, NO. 9, SEPTEMBER 2011, pp. 3048-3051). The research includes a description that even if the doping layer is partially removed through the replacement of the n-type semiconductor layer with the LiF/Al Schottky junction, it is possible to achieve an efficiency characteristic of a solar cell at an appropriate level.

However, in the research, the p-type semiconductor is still included as the doping layer, so that the aforementioned problems due to the doping layers are not completely resolved. Accordingly, follow-up researches are necessary.

### SUMMARY OF THE INVENTION

The present invention has been made in an effort to provide a thin film solar cell without a doping layer (a p-type semiconductor layer and an n-type semiconductor layer) and a method of manufacturing the same.

An exemplary embodiment of the present invention provides a thin film solar cell including: a substrate; a front electrode layer formed on the substrate; an oxide layer formed on the front electrode layer; a light absorbing layer (intrinsic layer) formed on the oxide layer; and a back electrode layer formed on the light absorbing layer, wherein the oxide layer is formed of a material selected from MoO₃, WO₃, V₂O₅, NiO and CrO₃.

In this case, a thickness of the oxide layer may be in range from 1 nm to 30 nm.

Further, the back electrode layer may include a first electrode layer formed on the light absorbing layer; and a second electrode layer formed on the first electrode layer, in which the first electrode layer may be formed of a material selected from LiF, Liq, Cs, CsI, CsCl, ZrO₂, Al₂O₃, Al, Mg and SiO₂, and the second electrode layer may be formed of a material selected from Al, Ag, Mg, Ca, and Li.

In this case, the first electrode layer may be formed of LiF and the second electrode layer may be formed of Al.

Further, a thickness of the first electrode layer may be in range from 0.1 nm to 5.0 nm.

In the meantime, the substrate may be a glass substrate coated with a fluorine tin oxide (FTC)).

Further, the front electrode layer may be formed of a material selected from a group consisting of a FTO, an indium tin oxide (ITO), ZnO:Al, ZnO:Ga, ZnO, ITO/AgO, and a combination thereof, or may be formed of a double layer made of ITO/GZO, ITO/ZnO or ITO/AZO.

Further, the light absorbing layer may be selected from an amorphous silicon (a-Si:H) thin film, a micro-crystalline silicon (mc-Si:H) thin film, a crystalline silicon (Si:H) thin film, a polycrystalline silicon (pc-Si:H) thin film, and a nano-crystalline silicon (nc-Si:H) thin film.

Another exemplary embodiment of the present invention provides a method of manufacturing the thin film solar cell according to the exemplary embodiment of the present invention, in which the oxide layer may be formed using a thermal evaporation method, a sputtering process, an E-beam evaporation method or Sol-gel solution process.

In this case, the back electrode layer may include the first electrode layer formed on the light absorbing layer and the second electrode layer formed on the first electrode layer, and the oxide layer and the back electrode layer may be formed using the thermal evaporation method, and the oxide layer may be formed to have a thickness in range from 10 nm to 30 nm and the first electrode layer may be formed to have a thickness in range from 1.0 nm to 5.0 nm.

Further, the back electrode layer may include the first electrode layer formed on the light absorbing layer and the second electrode layer formed on the first electrode layer, the oxide layer may be formed using the sputtering process and the back electrode layer may be formed using the thermal evaporation method, and the oxide layer may be formed to have a thickness in range from 5 nm to 10 nm and the first electrode layer may be formed to have a thickness in range from 1.0 nm to 5.0 nm.

According to exemplary embodiments of the present invention, the p-type semiconductor layer is replaced with the oxide layer and the n-type semiconductor is replaced with the back electrode layer formed of LiF/Al in the thin film solar cell having the p-i-n structure in the related art, thereby implementing the thin film solar cell without a doping layer.

Accordingly, the thin film solar cell according to the exemplary embodiment of the present invention does not have the problems, such as low light stability, generation of toxic gas, and an increase in process costs, created when the doping layers exist, and has the advantages, such as relatively high light stability, an eco-friendly property, and the reduction of process costs.

### BRIEF DESCRIPTION OF THE DRAWINGS

FIG. 1 is a cross-sectional view schematically illustrating a structure of a thin film solar cell according to an exemplary embodiment of the present invention.

FIG. 2 is a graph illustrating current density-voltage (I-V) characteristics of Comparative Example 1 and Examples 1 to 3.

FIG. 3 is a graph illustrating current density-voltage (I-V) characteristics in a darkroom of Comparative Example 2 and Examples 4 to 9.

FIG. 4 is a graph illustrating current density-voltage (I-V) characteristics of Comparative Example 1 and Examples 4 to 9.

FIG. 5 and FIG. 6 are a graph illustrating an efficiency change according to a time in Comparative Examples and Examples.

FIG. 7 is a graph illustrating current density-voltage (I-V) characteristics of Examples 14 to 17.

### DETAILED DESCRIPTION OF THE EMBODIMENTS

Hereinafter, an exemplary embodiment of the present invention will be described with reference to the accompanying drawings in detail.

Expressions, such as “upper part”, “on”, or “above”, may be used herein to describe a relative position concept based on the accompanying drawings, and those expressions may include a case in which another element or layer may not only directly exist in a mentioned layer, but also a case in which there may be another intervening layer or element therebetween, or another layer or element may exist on the mentioned layer, but may not completely cover a surface (especially, a surface having a 3D shape) of the mentioned layer. Likewise, expressions, such as “lower”, “in a lower side”, or “under” may also be understood as a relative concept for a position between a specific layer (element) and another layer (element).

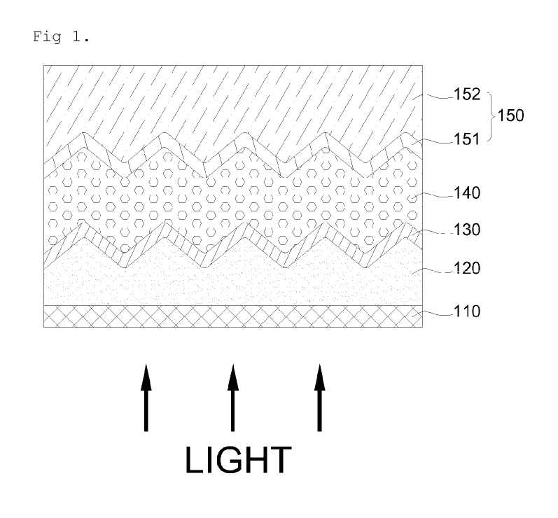

FIG. 1 is a cross-sectional view schematically illustrating a structure of a thin film solar cell 100 (hereinafter, referred to as a “thin film solar cell”) according to an exemplary embodiment of the present invention.

Referring to FIG. 1, the thin film solar cell 100 may have a structure in which a front electrode layer 120, an oxide layer 130, a light absorbing layer 140, and a back electrode layer 150 are sequentially formed on a substrate 110.

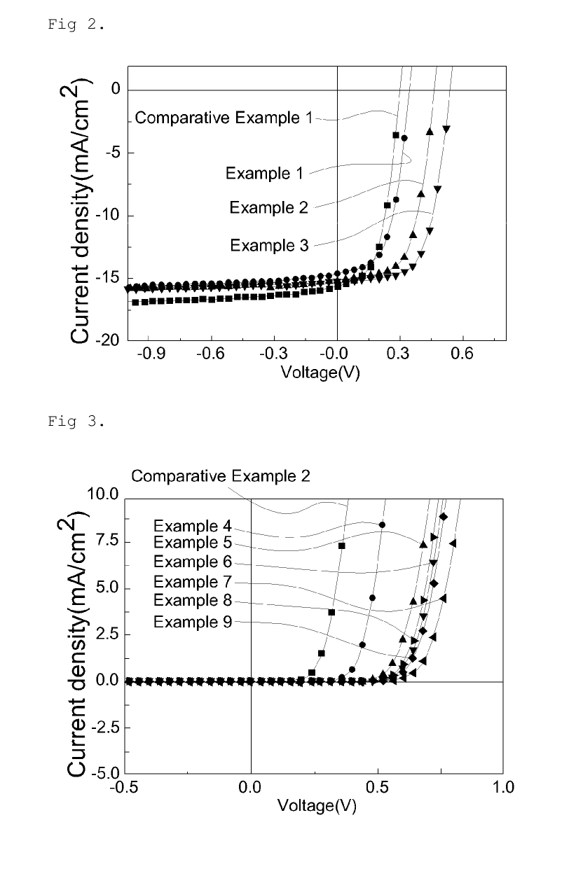

In the meantime, a plurality of amorphous embossing having a pyramid structure may be formed on one surface or both surfaces of the substrate 110, the front electrode layer 120, the oxide layer 130, the light absorbing layer 140, and the back electrode layer 150. That is, the elements may be provided with a texturing surface. The texturing surface may contribute to improve the efficiency of the solar cell by reducing the reflectance of incident light and increasing a movement route at an inside of the light absorbing layer 140 by scattering the incident light. FIG. 2 illustrates the thin film solar cell 100 provided with the texturing surface.

Hereinafter, each element of the thin film solar cell 100 will be described.

The substrate 110 may be made of a transparent material such that the incident light effectively reaches the light absorbing layer 140. That is, the substrate 110 may include a glass substrate or a transparent plastic substrate. An Example of the substrate 110 may be a glass substrate coated with fluorine tin oxide (FTO), a substrate coated with indium tin oxide (ITO), a dual substrate including a substrate coated with gallium zinc oxide (GZO), or a substrate coated with aluminum zinc oxide (AZO), but the substrate 110 is not limited thereto.

In this case, when the substrate 110 is a glass substrate coated with the FTO, the FTO may function as the front electrode layer 120.

The front electrode layer 120 collects and outputs one (for Example, a hole) of carriers generated by the incident light, and may be made of a transparent material and a material having electrical conductivity in order to increase transmittance of the incident light.

For Example, the front electrode layer 120 may be formed of a double layer made of a tin-based oxide (SnO₂, SnO₂:F, and ITO), an ITO/gallium zinc oxide (GZO), ITO/GZO or ITO/AZO, or may be formed of a material selected from the group consisting of ZnO:Al, ZnO, ITO/AgO, and a combination thereof.

The oxide layer 130 is formed on the front electrode layer 120. A technical characteristic of the thin film solar cell 100 according to the exemplary embodiment of the present invention is that the p-type semiconductor layer as one of the doping layers in the thin film solar cell in the related art is replaced with the oxide layer 130 made of a material selected from MoO₃ (molybdenum oxide), WO₃ (tungsten oxide), V₂O₅ (vanadium oxide), NiO (Nickel oxide) and CrO₃ (chromium oxide). In the meantime, the present specification provides the description based on the oxide layer made of MoO₃ for the convenience of description.

In order to exert the function identical or similar to that of the p-type semiconductor layer (a-Si:H) in the thin film solar cell in the related art, the oxide layer 130 is required to have a wide optical band gap, as well as appropriate electrical conductivity.

In connection with this, the MoO₃ has high electrical conductivity and a wide optical band gap (3.16 eV), so that it corresponds to a material satisfying the aforementioned conditions. The inventors of the present invention confirmed that because the oxide layer 130 made of the enumerated oxide materials, such as the MoO₃, is not the doping layer, contrary to the p-type semiconductor layer, the oxide layer 130 may solve the problem generated due to the doping layer while replacing the p-type semiconductor layer.

Specifically, when the p-type semiconductor layer of the thin film solar cell in the related art is replaced with the oxide layer 130 as described in the exemplary embodiment of the present invention in order to resolve the problem generated by the doping layer, it shows the further improvement of the characteristic compared to a case of the simple removal of the p-type semiconductor layer.

First, an absorption loss of the light generated in the p-type semiconductor layer in the related art may be reduced according to the wide optical band gap of the MoO₃ material. Second, series resistance may be reduced and a fill factor (FF) may be improved according to the high electrical conductivity of the MoO₃ material. Third, a high open circuit voltage Voc may be achieved according to a high work function of the MoO₃ material.

Fourth, the doping layer is replaced with the oxide material, so that the defect due to the doping layer is not generated and the MoO₃ material may function as a capping layer in an entire surface of the light absorbing layer, thereby improving the light stability of the solar cell.

Fifth, the toxic gas generated during the process of forming the doping layer is not generated and the oxide layer may be formed using the thermal evaporation process or the sputtering process, so that the use of the PECVD process may be remarkably reduced, thereby reducing process costs. These advantages will be supplementarily described in Test Examples to be described below.

The thickness of the oxide layer 130 is not specially limited, but is preferably in range from 1 nm to 30 nm. When the thickness of the oxide layer 130 is smaller than 1 nm or is larger than 30 nm, the efficiency characteristic of the thin film solar cell 100 that is the object of the present invention may not be sufficiently achieved. This will be supplementarily described in a Test Example to be described below.

The light absorbing layer (intrinsic layer) 140 is formed on the oxide layer 130 and serves to generate electron-hole pairs and generate the current by receiving the incident light.

The light absorbing layer 140 may use an amorphous silicon (a-Si:H) thin film, a micro-crystalline silicon (mc-Si:H) thin film, a crystalline silicon (Si:H) thin film, a polycrystalline silicon (pc-Si:H) thin film, or a nano-crystalline silicon (nc-Si:H) thin film, but the light absorbing layer 140 is not limited thereto. For the convenience of description, a description will be given based on a case in which the light absorbing layer 140 is the amorphous silicon thin film in the present specification. In the meantime, the thickness of the light absorbing layer 140 is not limited, and for Example, the light absorbing layer 140 may be to have a thickness in range from 50 nm to 1,000 nm.

The back electrode layer 150 is formed on the light absorbing layer 140 and may include a first electrode layer formed on the light absorbing layer 140 and a second electrode layer 152 formed on the first electrode layer 151.

In this case, the first electrode layer 151 may be formed of a material selected from LiF, Liq, Cs, CsI, CsCl, ZrO₂, Al₂O₃, Al, Mg and SiO₂, but the first electrode layer 151 is not limited thereto. Further, the second electrode layer 152 may be formed of a material selected from Al, Ag, Mg, Ca, and Li, but the second electrode layer 152 is not limited thereto. For Example, a combination of the first electrode layer 151 and the second electrode layer 152 may be LiF/Al, ZrO₂/Al, ZrO₂/Ag, ZrO₂/Mg, ZrO₂/Ca, ZrO₂/Li, Al₂O₃/Al, Al₂O₃/Ag, SiO₂/Al, SiO₂/Ag, and the like, but the combination is not limited thereto.

In the thin film solar cell 100 according to the exemplary embodiment of the present invention, the n-type semiconductor layer (see FIG. 1) that is one of the doping layers of the thin film solar cell in the related art is removed and is replaced with the back electrode layer 150 including the first electrode layer 151 and the second electrode layer 152. In the meantime, for the convenience of description, a description will be given based on a case where LiF/Al is used as the back electrode layer 150 in which the first electrode layer 151 is LiF and the second electrode layer 152 is Al, in the present specification.

The first electrode layer 151/second electrode layer 152 is a Schottky junction and may replace the n-type semiconductor layer in the thin film solar cell. This is described in [Non-Patent Document] (Liang Fang et. al., IEEE TRANSACTIONS ON ELECTRON DEVICES, VOL. 58, NO. 9, SEPTEMBER 2011, pp. 3048-3051) in detail, and the present specification includes the contents of the Non-Patent Document.

The first electrode layer 151 may function as surface passivation. The thickness of the first electrode layer 151 is not specially limited, but the first electrode layer 151 is preferably formed to have a thickness in range from 0.1 nm to 5.0 nm. If the thickness of the first electrode layer 151 is out of the range, the efficiency characteristic of the thin film solar cell 100 that is the object of the present invention may not be sufficiently achieved. This will be supplementarily described in a Test Example to be described below.

In the meantime, the second electrode layer 152 may collect and output one (for Example, an electron) of the carriers generated by the incident light.

Hereinafter, a method of manufacturing a thin film solar cell according to an exemplary embodiment of the present invention will be described. For the convenience of description, the components of the thin film solar cell according to the exemplary embodiment of the present invention will be indicated by the same reference numbers.

First, a front electrode layer 120 is formed on a substrate 110, or a FTO glass coated with FTO is prepared. The front electrode layer 120 may use a double layer formed of a tin-based oxide (SnO₂, SnO₂: F, and ITO), an iTO/gallium zinc oxide (GZO), ITO/GZO or ITO/AZO, or a material selected from the group consisting of ZnO:Al, ZnO, ITO/AgO, and a combination thereof.

Next, an oxide layer 130 is deposited on the front electrode layer 120. The oxide layer 130 may be formed of a material selected from MoO₃ (molybdenum oxide), WO₃ (tungsten oxide), V₂O₅ (vanadium oxide), NiO (Nickel oxide) and CrO₃ (chromium oxide).

In this case, a thermal evaporation method, a sputtering process, an E-beam evaporation process, or Sol-gel solution process under a condition of a vacuum of Low 10⁻⁶ Torr may be used as a deposition method.

Next, a light absorbing layer 140 formed of an amorphous silicon (a-Si:H) thin film, a micro-crystalline silicon (mc-Si:H) thin film, a crystalline silicon (Si:H) thin film, a polycrystalline silicon (pc-Si:H) thin film, or a nano-crystalline silicon (nc-Si:H) thin film is deposited on the oxide layer 130 by using a PECVD process, a photo-CVD process, a laser CVD process, a sputtering process, or the like, and a first electrode layer 151 formed of a material selected from LiF, Liq, Cs, CsI, CsCl, ZrO₂, Al₂O₃, Al, Mg and SiO₂, and a second electrode layer 152 formed of a material selected from Al, Ag, Mg, Ca, and Li may be formed on the light absorbing layer 140 again by using the thermal evaporation method or the sputtering process, to manufacture the thin film solar cell.

The thin film solar cell having the p-i-n structure in the related art has a problem in the increase in the process costs because the doping layers, such as the p-type semiconductor layer and the n-type semiconductor layer, are deposited using the PECVD process. However, the thin film solar cell according to the exemplary embodiment of the present invention has an advantage of reducing the entire process costs because the oxide layer 130 and the back electrode layer 150, which are not the doping layers, may be formed through the thermal evaporation method or the sputtering process of which the process costs are lower than those of the PEDVD process. Further, since the doping layer is not required to be formed, there is no toxic gas generated while the doping layer is formed, so that the thin film solar cell may be manufactured as eco-friendly.

As described above, in the exemplary embodiments of the present invention, the p-type semiconductor layer of the thin film solar cell having the p-i-n structure in the related art is replaced with the oxide layer formed of the material selected from MoO₃, WO₃, V₂O₅, NiO and CrO₃, and the n-type semiconductor is replaced with the back electrode layer including the first electrode layer formed of the material selected from LiF, Liq, Cs, CsI, CsCl, ZrO₂, Al₂O₃, Al, Mg and SiO₂ and the second electrode layer formed of the material selected from Al, Ag, Mg, Ca, and Li, thereby implementing the thin film solar cell including no doping layer. Accordingly, the thin film solar cell according to the exemplary embodiment of the present invention does not have the problem, such as low light stability, the generation of the toxic gas, and the increase in the process costs, created when the doping layers exist, and has the advantages, such as relatively high light stability, an eco-friendly property, and the reduction of the process costs.

Hereinafter, a Test Example of the present invention will be described. However, it is obvious that the Test Example below does not limit the present invention.

### Test Example

### Preparation of Comparative Example and Example

For the test, the thin film solar cells corresponding to the Comparative Examples and the Examples were manufactured, and Comparative Example and the Example are organized in Table 1 below. In the meantime, the light absorbing layer was formed to have a thickness of 450 nm by using a-SI:H as a material thereof, and FTO glass (manufactured by Pilkington Glass Company) was used for the substrate and the front electrode layer.

TABLE 1

| | |
|---|---|
| Comparative | FTO/a-Si:H (450 nm)/LiF (0.7 nm)/Al |
| Example 1 | |
| Comparative | FTO/a-Si:H (450 nm)/LiF (1 .4 nm)/Al |
| Example 2 | |
| Example 1 | FTO/MoO₃ (1 nm)/a-Si:H (450 nm)/LiF (0.7 nm)/Al |
| Example 2 | FTO/MoO₃ (5 nm)/a-Si:H (450 nm)/LiF (0.7 nm)/Al |
| Example 3 | FTO/MoO₃ (10 nm)/a-Si:H (450 nm)/LiF (0.7 nm)/Al |
| Example 4 | FTO/MoO₃ (5 nm)/a-Si:H (450 nm)/LiF (1.4 nm)/Al |
| Example 5 | FTO/MoO₃ (10 nm)/a-Si:H (450 nm)/LiF (1.4 nm)/Al |
| Example 6 | FTO/MoO₃ (15 nm)/a-Si:H (450 nm)/LiF (1.4 nm)/Al |
| Example 7 | FTO/MoO₃ (20 nm)/a-Si:H (450 nm)/LiF (1.4 nm)/Al |
| Example 8 | FTO/MoO₃ (25 nm)/a-Si:H (450 nm)/LiF (1.4 nm)/Al |
| Example 9 | FTO/MoO₃ (30 nm)/a-Si:H (450 nm)/LiF (1.4 nm)/Al |

Referring to Table 1, the Comparative Examples and the Examples may be divided according to existence of the oxide layer, and specifically, in the Comparative Examples, the p-type semiconductor layer was removed in the thin film solar cell in the related art, and in the Examples, the p-type semiconductor layer was replaced with the oxide layer. In this case, MoO₃ was used for the oxide layer, and the thermal evaporation method was used for the method of forming the oxide layer.

In all of the Comparative Examples and the Examples, the n-type semiconductor layer in the thin film solar cell in the related art was replaced with the back electrode layer formed of LiF/Al, and the thermal evaporation method was used for the method of forming the back electrode layer. Further, the thicknesses of LiF were different in Comparative Examples 1 and 2, and the thicknesses of the oxide layer (MoO₃) and LiF were different in the Examples.

In the meantime, for Comparative Example 2 and Examples 6 to 9 represented in Table 1, FTO glass manufactured by a different manufacturing Company (Asahi Glass Company) was used for the substrate and the front electrode layer. This is organized in Table 2 below.

TABLE 2

| | |
|---|---|
| Comparative | FTO/a-Si:H(450 nm)/LiF(1.4 |
| Example 3 | nm)/Al |
| Example 10 | FTO/MoO₃(15 nm)/a-Si:H(450 |
| | nm)/LiF(1.4 nm)/Al |
| Example 11 | FTO/MoO₃(20 nm)/a-Si:H(450 |
| | nm)/LiF(1.4 nm)/Al |
| Example 12 | FTO/MoO₃(25 nm)/a-Si:H(450 |
| | nm)/LiF(1.4 nm)/Al |
| Example 13 | FTO/MoO₃(30 nm)/a-Si:H(450 |
| | nm)/LiF(1.4 nm)/Al |

Note:
FTO glass (Asahi Glass Company)

Referring to Table 2, Comparative Example 3 and Examples 10 to 13 have the same configuration as that of Comparative Example 2 and Examples 6 to 9 in Table 1, except for the FTO glass.

In the meantime, the thin film solar cells corresponding to Examples 14 to 17 were manufactured, and are organized in Table 3 below.

FTO glass (manufactured by Pilkington Glass Company) was used for the substrate and the front electrode layer in Examples 14 to 17, and the light absorbing layer was formed to have a thickness of 450 nm by using a-SI:H as a material thereof. Further, MoO₃ was used for the oxide layer, and the sputtering process was used for the method of forming the oxide layer, differently from Examples 1 to 9.

In all of the Examples 14 to 17, the n-type semiconductor layer in the thin film solar cell in the related art was replaced with the back electrode layer formed of LiF/Al, and the thermal evaporation method was used for the method of forming the back electrode layer. Further, the thickness of LiF was 1.4 nm, and the thicknesses of the oxide layer were different. The Examples 14 to 17 are organized in Table 3 below.

TABLE 3

| | |
|---|---|
| Example 14 | FTO/MoO₃(3 nm)/a-Si:H(450 |
| | nm)/LiF(1.4 nm)/Al |
| Example 15 | FTO/MoO₃(5 nm)/a-Si:H(450 |
| | nm)/LiF(1.4 nm)/Al |
| Example 16 | FTO/MoO₃(7.5 nm)/a- |
| | Si:H(450 nm)/LiF(1.4 nm)/Al |
| Example 17 | FTO/MoO₃(10 nm)/a-Si:H(450 |
| | nm)/LiF(1.4 nm)/Al |

Note:
The sputtering process was used for the method of forming the oxide layer.

Measurement of energy conversion efficiency In order to measure the characteristics of the thin film solar cells manufactured in the enumerated Comparative Examples and Examples, open circuit voltage (Voc), a short-circuit current density (J_{sc}), a fill factor (FF), and energy conversion efficiency were measured (Oriel 300 W, standard condition: 100 mW/cm², 25° C.). The measurement result is represented in Table 4 below.

TABLE 4

| | Short-circuit | | Fill | |
|---|---|---|---|---|
| | current | Open circuit | Factor | Efficiency |
| | (J_{sc}, mA/cm²) | voltage (Voc, V) | (%) | (%) |
| Comparative | 15.59 | 0.29 | 0.53 | 2.48 |
| Example 1 | | | | |
| Comparative | 14.97 | 0.31 | 0.50 | 2.35 |
| Example 2 | | | | |
| Comparative | 15.58 | 0.38 | 0.53 | 3.21 |
| Example 3 | | | | |
| Example 1 | 14.62 | 0.34 | 0.55 | 2.79 |
| Example 2 | 15.11 | 0.46 | 0.60 | 4.24 |
| Example 3 | 15.23 | 0.53 | 0.63 | 5.20 |
| Example 4 | 14.88 | 0.47 | 0.60 | 4.23 |
| Example 5 | 15.39 | 0.61 | 0.58 | 5.53 |
| Example 6 | 15.27 | 0.66 | 0.64 | 6.55 |
| Example 7 | 14.66 | 0.72 | 0.65 | 6.98 |
| Example 8 | 14.99 | 0.65 | 0.64 | 6.36 |
| Example 9 | 13.99 | 0.67 | 0.64 | 6.07 |
| Example 10 | 16.65 | 0.68 | 0.62 | 7.06 |
| Example 11 | 15.65 | 0.68 | 0.62 | 6.71 |
| Example 12 | 14.72 | 0.69 | 0.62 | 6.45 |
| Example 13 | 14.50 | 0.67 | 0.61 | 6.02 |
| Example 14 | 15.88 | 0.49 | 0.62 | 4.87 |
| Example 15 | 16.32 | 0.62 | 0.66 | 6.59 |
| Example 16 | 16.08 | 0.65 | 0.67 | 7.08 |
| Example 17 | 14.27 | 0.66 | 0.68 | 6.43 |

Case where the Thickness of LiF is 0.7 nm

FIG. 2 is a graph illustrating current density-voltage (I-V) characteristics of the Comparative Example 1 and the Examples 1 to 3. In the Comparative Example 1 and the Examples 1 to 3, LiF was formed to have a thickness of 0.7 nm.

Referring to FIG. 2, it could be seen that the efficiency of the Examples 1 to 3 was improved compared to the Comparative Example 1. Further, it could be seen that the open circuit voltage V_{oc} and the fill factor were also improved. Especially, it could be seen that the efficiency in a case where the thickness of the oxide layer was 10 nm (Example 3) was two times or more than that of the Comparative Example 1.

However, it could be seen that the short-circuit currents J_{sc} in the Examples 1 to 3 were at a level lower than that of the Comparative Example 1. This is because when the p-type semiconductor layer is removed in the thin film solar cell in the related art (Comparative Example 1), there is no absorption loss in the p-type semiconductor layer, so that the short-circuit current is improved. However, it could be seen that as the thickness of the oxide layer is thick, a value of the short-circuit current gradually increases, and when the thickness of the oxide layer is equal to or larger than 10 nm (Example 3), the value of the short-circuit current is the value of the short-circuit current at a level equivalent to the Comparative Example 1.

Case in which the Thickness of LiF is 1.4 nm

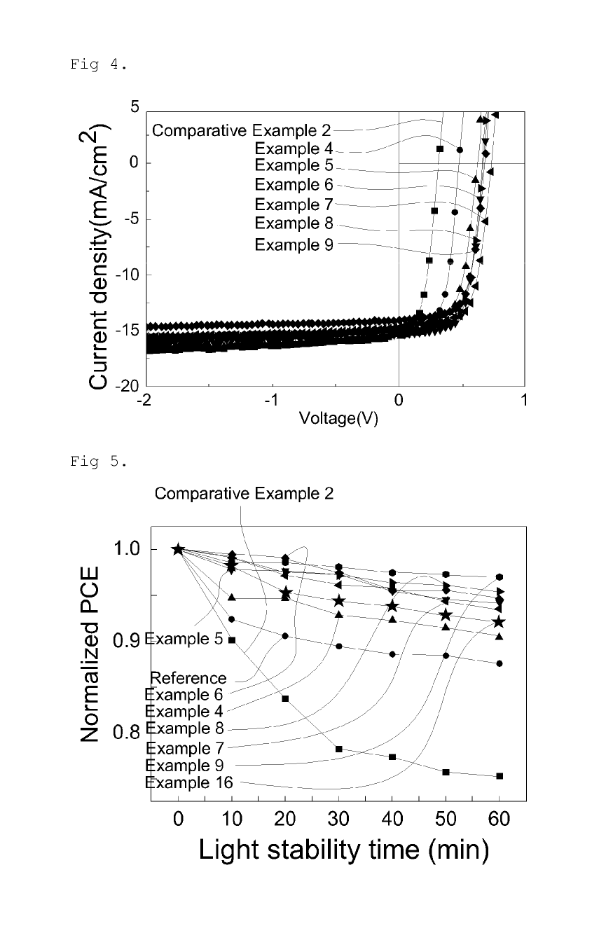

FIG. 3 is a graph illustrating current density-voltage (I-V) characteristics in a darkroom of the Comparative Example 2 and the Examples 4 to 9, and FIG. 4 is a graph illustrating current density-voltage (I-V) characteristics of the Comparative Example 1 and the Examples 4 to 9. LiF in the Comparative Example 2 and the Examples 4 to 9 were formed to have the thickness of 1.4 nm.

Referring to FIGS. 3 and 4, it could be seen that the open circuit voltage V_{oc}, the fill factor, and the efficiency of the Examples 4 to 9 were improved compared to the Comparative Example 2 like the aforementioned Examples. Especially, it could be seen that in a case where the thickness of the oxide layer ranges from 10 nm to 30 nm (Examples 5 to 9), the efficiency was two times or more than that of the Comparative Example 2 and the maximum efficiency was measured as 6.98% (Example 7). This result was obtained because series resistance was decreased due to the high electrical conductivity of the oxide layer so that the fill factor was improved, and the open circuit voltage V_{oc} was increased because the oxide layer had a high work function.

In the meantime, it was identified that in a case where the FTO glass manufactured by Asahi Glass Company was used, the efficiency for a specific thickness of the oxide layer was further improved when the other conditions were the same. Particularly, it was identified that the efficiency (7.06%) was higher than the efficiency (6.55%) of Example 6 in the Example 10, which had the same conditions as Example 6 except for the FTO glass. Further, it was identified that in a case where the FTO glass of Pilkington Glass Company was used, the highest efficiency was obtained when the thickness of the oxide layer (MoO₃) was 20 nm, and in a case where the FTO glass of Asahi Glass Company was used, the highest efficiency was obtained when the thickness of the oxide layer (MoO₃) was 15 nm.

Measurement of Light Stability

FIG. 5 and FIG. 6 are a graph illustrating an efficiency change according to a time in the Comparative Examples and the Examples. FIG. 5 is a graph illustrating an efficiency change for 1 hour, FIG. 6 is a graph illustrating an efficiency change for 10 hours.

In order to measure light stability, light was irradiated to the thin film solar cells of the comparative 2, the Examples 4 to 9, and the Example 16, to measure a degree of the efficiency degradation (see Table 2 for the initial efficiency). In the meantime, the thin film solar cell having the p-i-n structure in the related art was also represented in the graph as a reference.

Referring to FIG. 5 and FIG. 6, it could be identified that the efficiency of the comparative 2 was sharply decreased as time passed, but the efficiency decrease of the Examples 4 to 9 was far less compared to the Comparative Example 2. Further, it could be identified that the efficiency decrease of the Examples 4 to 9 was smaller than that of the thin film solar cell (reference) having the p-i-n structure in the related art (also, it had similar results in FIG. 6).

This is because in a case (Comparative Example 2) where there is no p-type semiconductor layer, the degradation phenomenon is accelerated because the light is directly irradiated to the light absorbing layer (intrinsic layer) and the energy level is not proper, but in the p-i-n structure, the degradation phenomenon occurs less because the light passes through the p-type semiconductor layer once and in addition to a proper energy level, compared to the case where there is no p-type semiconductor layer.

However, in the p-i-n structure, a defect phenomenon occurs due to the p-type semiconductor layer and the n-type semiconductor layer; however, the defect phenomenon does not occur in a case where there is no doping layer like the Examples, so that light stability may be improved.

In the meantime, it was identified that the light stability of the Example 16 in which the oxide layer was formed using the sputtering process was excellent compared to the Comparative Example 2 and the thin film solar cell (reference) having the p-i-n structure in the related art. This result shows that because the oxide layer formed by the sputtering process is more compact than the thin film formed by the thermal evaporation method, light stability at the same level may be secured while the film having a thin thickness is formed, so that the manufacturing costs may be reduced.

That is, through the tests, it can be seen that a more excellent and stable solar cell may be implemented in a case where the p-type semiconductor layer is replaced with the oxide layer, than in a case where the p-type semiconductor layer is removed in the thin film solar cell having the p-i-n structure in the related art.

Case in which the Sputtering Process is Used

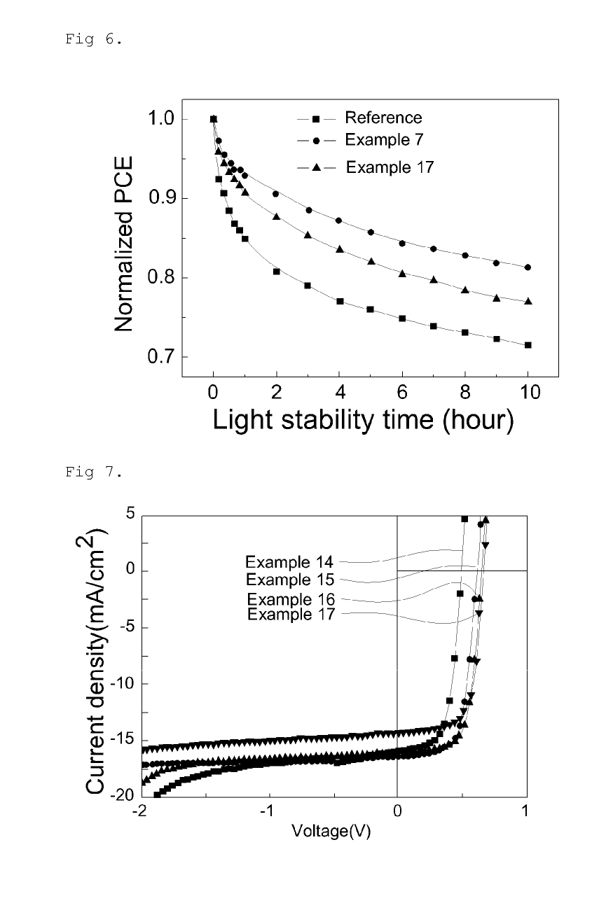

FIG. 7 is a graph illustrating current density-voltage (I-V) characteristics of the Examples 14 to 17.

Referring to FIG. 6, it could be seen that, like the aforementioned test result, the open circuit voltage V_{oc}, the fill factor, and the efficiency were improved in a case where there was the oxide layer (MoO₃), compared to a case where there was no oxide layer (MoO₃) (see Comparative Examples 2 and 3 of Table 4).

In the meantime, in a case where the oxide layer was formed by the sputtering process, not the thermal evaporation method, the maximum efficiency was measured as 7.08% when the thickness of the oxide layer was 7.5 nm (Example 16). This is different from a case (Example 7) in which the maximum efficiency was measured when the thickness of the oxide layer was 20 nm when the thermal evaporation method is used, such that it can be identified that an appropriate thickness of the oxide layer is induced according to the oxide layer forming process. However, it was identified that high efficiency was achieved in any case compared to a case (Comparative Examples 1, 2, and 3) where there was no oxide layer (MoO₃).

In this case, an area having an optimum thickness of the oxide layer formed by the sputtering process is smaller than that of the oxide layer formed by the thermal evaporation method. The reason is that the thin film formed by the sputtering process is more compact than that formed by the thermal evaporation method. Accordingly, when the oxide layer is formed by the sputtering process, the efficiency in the same level may be secured while the film is formed to have a thin thickness compared to a case where the oxide layer is formed by the thermal evaporation, so that the manufacturing costs may be advantageously reduced. The inventors of the present invention induced the optimum thickness of the oxide layer in the sputtering process having the highest productivity in an aspect of film uniformity and process stability of a large area substrate using the semiconductor process as described, so that the productivity of the thin film solar cell may be significantly improved.

Although an exemplary embodiment of the present invention has been described, those skilled in the art will variously modify and change the present invention through supplement, change, deletion, addition of the constituent element, and the like, without departing from the spirit of the present invention defined in the claims, and the modification and the change will belong to the scope of the right of the present invention.

1. A thin film solar cell comprising:
a substrate;
a front electrode layer formed on the substrate;
an oxide layer formed on the front electrode layer a light absorbing layer (instrinsic layer) formed on the oxide layer; and
a back electrode layer formed on the light absorbing layer,
wherein the oxide layer is formed of a material selected from MoO₃, WO₃, V₂O₅, NiO and CrO₃; and
wherein the cell lacks a doping layer.

2. The thin film solar cell of claim 1, wherein the oxide layer has a thickness in range from 1 nm to 30 nm.

3. The thin film solar cell of claim 1, wherein the back electrode layer comprises:
a first electrode layer formed on the light absorbing layer; and
a second electrode layer formed on the first electrode layer, wherein the first electrode layer is formed of a material selected from LiF, Liq, Cs, CsI, CsCl, ZrO₂, Al₂O₃, Al, Mg and SiO₂, and
The second electrode layer is formed of a material selected from Al, Ag, Mg, Ca and Li.

4. The thin film solar cell of claim 3, wherein the first electrode layer is formed of LiF and the second electrode layer is formed of Al.

5. The thin film solar cell of claim 3, wherein the first electrode layer has a thickness in range from 0.1 nm to 5.0 nm.

6. The thin film solar cell of claim 1, wherein the substrate is a glass substrate coated with a fluorine tin oxide (FTO).

7. The thin film solar cell of claim 1, wherein the front electrode layer is formed of a material selected from a group consisting of a FTO, an indium tin oxide (ITO), ZnO:Al, ZnO:Ga, ZnO, ITO/AgO, and a combination thereof, or is formed of a double layer made of ITO/GZO, ITO/ZnO or ITO/AZO.

8. The thin film solar cell of claim 1, wherein the light absorbing layer is selected from an amorphous silicon (a-Si:H) thin film, a micro-crystalline silicon (mc-Si:H) thin film, a crystalline silicon (Si:H) thin film, a polycrystalline silicon (pc-Si:H) thin film, and a nano-crystalline silicon (nc-Si:H) thin film.
